(19) United States
(12) Patent Application Publication
(10) Pub. No.: US 2004/0224501 A1
(43) Pub. Date: Nov. 11, 2004

(54) MANUFACTURING METHOD FOR MAKING TUNGSTEN-PLUG IN AN INTERGRATED CIRCUIT DEVICE WITHOUT VOLCANO PHENOMENA

(76) Inventors: YUNG-TSUN LO, YI-LAN (TW); RAYMOND TSAI, TAICHUNG (TW); WEN-YU HO, YUNG KANG CITY (TW)

Correspondence Address: BACON & THOMAS, 625 SLATERS LANE, 4TH FLOOR, ALEXANDRIA, VA, 223141176

(21) Appl. No.: 09/243,433

(22) Filed: Feb. 8, 2002

Related U.S. Application Data
(63) Continuation-in-part of application No. 08/651,535, filed on May 22, 1996, now abandoned.

(51) Int. Cl. H01L 21/8238; H01L 21/44

(52) U.S. Cl. 438/672; 438/680; 438/685

(57) ABSTRACT

A method of making tungsten plug of integrated circuit is disclosed. The present invention is structured to deposit W metal by CVD onto the wafer which has Ti/TiN sputtered on as its top layer by employing quartz clamp rings of different sizes in two CVD chambers. The method can eliminate the Volcano phenomena in Ti, TiN or W metals and prevent peeling.

### BACKGROUND OF THE INVENTION

1. Field of the Invention

The invention relates to a method of making tungsten plugs in integrated circuit devices by a chemical vapor deposition process, and more particularly, to an improvement in the method which eliminates the volcano phenomena. The method of the present invention dramatically increases the efficiency of the method by producing fewer defective devices exhibiting the undesirable volcano phenomena.

2. Description of the Prior Art

It is widely known that Ti, W, TiN or Al alloys are used for metal interconnection in USLI technology. For example, the double level metal interconnection process used commercially today employs a Ti/TIN/W tri-layer structure to form the first level metal interconnection, in which the Ti is the bottom layer that makes electrical contact with the source and drain electrodes of the Field Effect Transistor devices.

Conventional methods of making the first level metal interconnection in the double level metal interconnection process include the following steps:

(1) Depositing a SiO₂ insulation layer on top of the contact hole and devices by chemical vapor deposition (CVD), then depositing a layer of BPSG (Boronphospliosilicate Glass) onto the SiO2 layer for surface planarization by employing CVD again;

(2) Forming contact holes as shown in FIGS. 1 and 2;

(3) Making ion implantation through the contact holes and forming the devices;

(4) Sputter depositing a barrier metal layer made up of Ti and TiN, in which the Ti metal is underneath the TiN; the barrier layer crosses the contact holes mentioned above;

(5) Depositing W metal to form the W-plug in the contact hole by plasma anisotropic etchback technique.

Using these methods, the Ti layer is about 300 angstroms thick and the TiN is about 1500 angstroms thick. The following reactions occur to form W metal by CVD:

WF₆(g)+SiH4(g)→W(s)+SiF₄(g)+H₂(g)

WF₆(g)+H₂(g)→W(s)+HF(g)

WF₆ is reacted with SiH4 in the first step of the process. Thereafter hydrogen gas (H₂(g)) is reacted with WF₆ which produces tungsten (W).

However, the Ti/TiN layer made in step (4) has a very poor step coverage capability. Therefore the Ti/TiN layer can be very thin near the top and bottom of the sidewalls of the contact holes, as shown in FIG. 3. As a consequence of this phenomenon, the WF₆ gas used for W metal deposition will penetrate the TiN layer and react with the Ti metal underneath to produce the evaporative TiF₄, which will result in an explosive phenomena near the contact hole. This is called the volcano phenomena. The reaction of Ti with WF₆ is as follows:

Ti(s)+WF₆(g)→W(s)+TiF₄(g)

This volcano phenomena can easily cause peeling of the Ti, TiN or W layers which makes the devices defective and thereby reduces the yield of acceptable devices produced by the process.

In addition, the deposited tungsten layer will not adhere to the surface of SiO₂ or BPSG. The TiN layer is deposited before the tungsten layer is formed as a barrier layer to avoid peeling. Since the TiN layer is deposited by sputtering, the volcano phenomenon is even more likely to happen near the edge of the silicon wafer. Because the wafer was held down by a quartz clamp ring inside the reaction chamber, some BPSG will be left near the edge of the wafer. This makes the tungsten nucleation layer insufficient near the edge and thus reduces the reaction speed for the WF₆ gas to produce the tungsten (W) metal. The overabundant WF₆ gas facilitates peeling of the tungsten (W) layer resulting in the production of defective devices which reduces the overall yield of acceptable devices manufactured by the process.

U.S. Pat. No. 5,489,552 the entire disclosure of which is herein incorporated by reference, relates to a multiple layer tungsten deposition process and discusses the volcano phoneme. U.S. Pat. No. 5,436,200, the entire disclosure of which is herein incorporated by reference, describes a blanket tungsten deposition process utilizing a ceramic ring.

### SUMMARY OF THE INVENTION

In view of the foregoing, the primary object of the present invention is to provide a high yield, low cost and highly efficient manufacturing process for making IC metal interconnections and avoiding the volcano phenomena.

This invention uses two CVD (chemical vapor deposition) chambers with clamp rings of different sizes to control the deposition area and thickness. This approach ensures that the bulk deposition of tungsten (W) is on the nucleation layer. Thus, the penetrating of excessive WF₆ gas into TiN barrier layer is avoided. This prevents the volcano phenomena from happening.

The process of the present invention comprises the following steps:

(1) Depositing a SiO₂ insulation layer (25) on top of a substrate (20) by CVD; and then depositing a layer of BPSG (30) onto the SiO₂ layer (20) for surface planarization by again employing CVD;

(2) Partially etching the SiO₂ insulation layer (25) and the BPSG layer (30) to form contact holes on the substrate (20);

(3) Making ion implantation through the contact hole and forming the devices;

(4) Sputter depositing a barrier metal layer made up of Ti followed by rapid thermal nitridation to form a TiN layer in which the Ti metal is underneath the TiN layer which is bilayer (40);

(5) Depositing tungsten (W) metal in two CVD chambers with different quartz clamp rings to control the area and thickness of the tungsten nucleation layer (50) and bulk deposition area of the tungsten (W) layer (60) in order to ensure the bulk deposition is onto the nucleation layer;

(6) Forming the tungsten-plug in the contact hole by plasma anisotropic etch back technique;

(7) Sputtering on a Al/Si/Cu layer and pattern metal lines by conventional technology.

The rapid thermal nitridation of step (4) may take place at, for example, 760° C. for 30 seconds.

### BRIEF DESCRIPTION OF THE DRAWINGS

The accompanying drawings further describe the prior art and the invention.

FIG. 1-3 show the cross-sectional representation of the conventional process for making the first level metal interconnection.

FIG. 1 shows the cross-sectional representation of the silicon wafer after SiO₂ deposition. The SiO₂ is used as an insulation layer.

FIG. 2 shows the cross-sectional representation after etching unwanted SiO₂ layer to make contact holes. The metal layer will form electrical contact to the devices.

FIG. 3 shows the cross-sectional representation of Ti and TiN deposition by sputtering. These metal layers contact the devices on the silicon wafer through the contact holes in the SiO₂ layer.

FIG. 4 shows the cross-sectional representation of the process of the invention for making the first level metal interconnection.

FIGS. 5A, 5B, and 5C show the top view and cross-sectional view of the three quartz (1, 2, 3) clamp rings of different size used in the CVD process in this invention.

FIG. 6 shows the system of operation procedure with the CVD chamber A and chamber B used in this invention for the deposition of tungsten (W) metal.

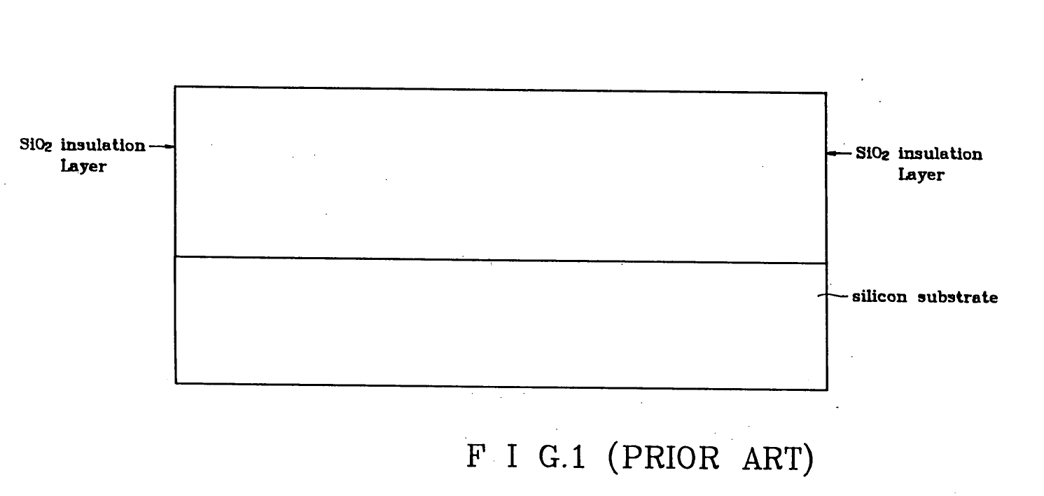

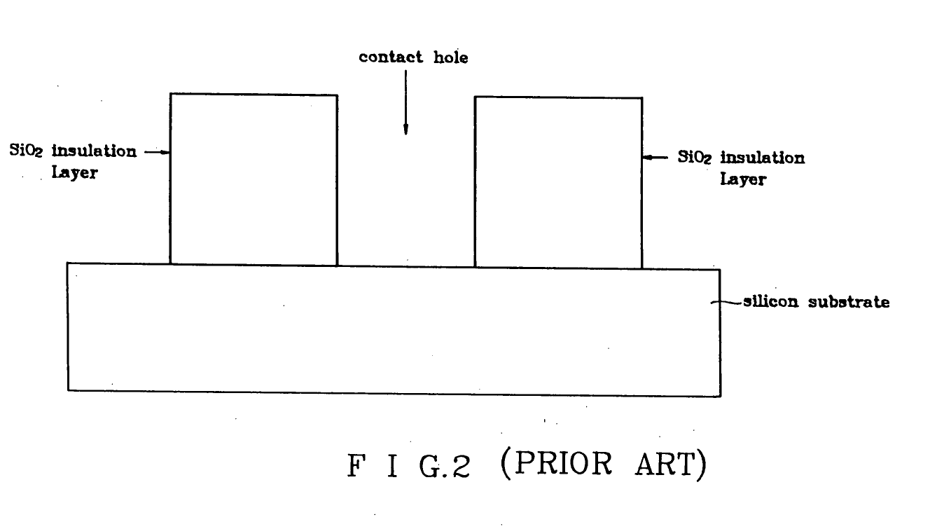

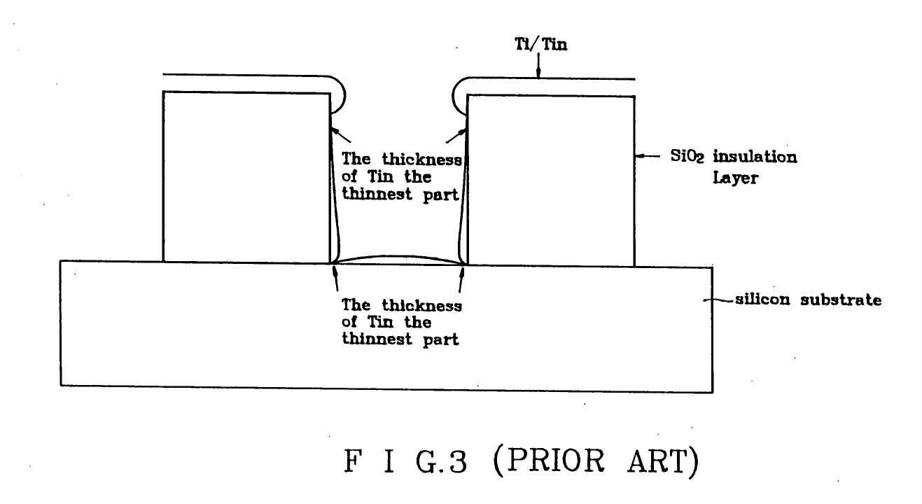

### DETAILED DESCRIPTION OF THE INVENTION

In the conventional method for making IC, a field contact hole is formed to insulate the active area from the silicon substrate, then the FET is made which contains the gate dielectric, the gate electrode, spacer and source/drain region. Thereafter the metal interconnection process is widely used today and has been described in the field of this invention mentioned above.

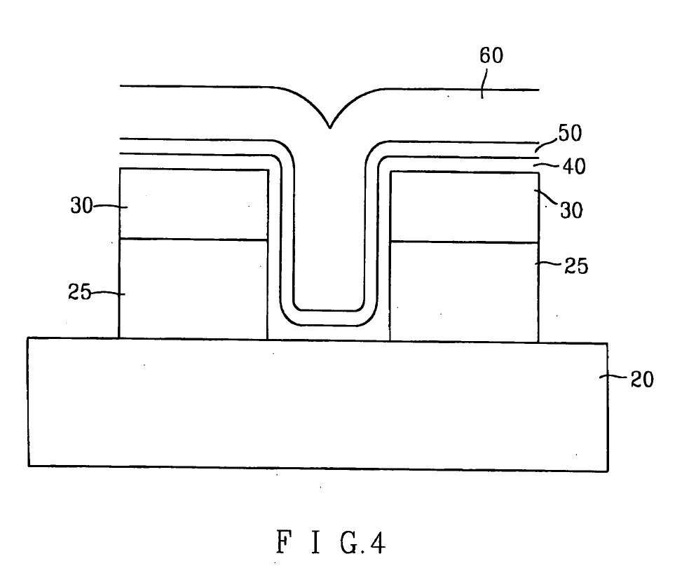

This invention improves the process for making the first level metallization in the double level metal interconnection process, to prevent the volcano phenomena and peeling of the metal layer. FIG. 4, depicts the cross-sectional view of the device made by the process of the present invention. The process comprises the following steps:

(1) Depositing a SiO₂ insulation layer (25) on top of a substrate (20) by CVD; and then depositing a layer of BPSG (30) onto the SiO₂ layer (20) for surface planarization by again employing CVD;

(2) Partially etching the SiO₂ insulation layer (25) and the BPSG layer (30) to form contact holes on the substrate (20);

(3) Making ion implantation through the contact hole and forming the devices;

(4) Sputter depositing a barrier metal layer made up of Ti followed by rapid thermal nitridation to form a TiN layer in which the Ti metal is underneath the TiN layer which is bilayer (40);

(5) Depositing tungsten (W) metal in two CVD chambers with different quartz clamp rings to control the area and thickness of the tungsten nucleation layer (50) and bulk deposition area of the tungsten (W) layer (60) in order to ensure the bulk deposition is onto the nucleation layer;

(6) Forming the tungsten-plug in the contact hole by plasma anisotropic etch back technique;

(7) Sputtering on a Al/Si/Cu layer and pattern metal lines by conventional technology.

The rapid thermal nitridation of step (4) may take place at, for example, 760° C. for 30 seconds.

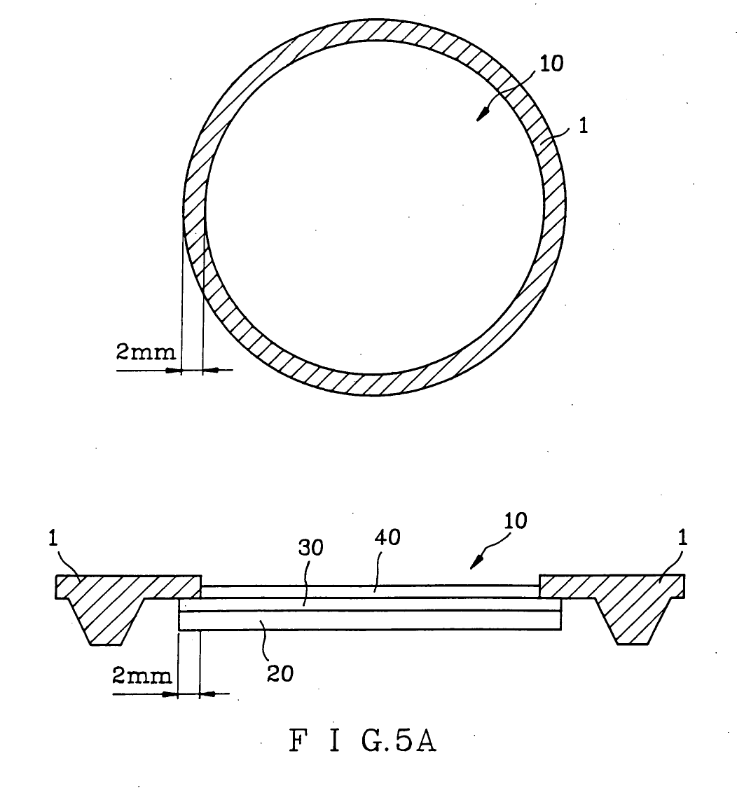

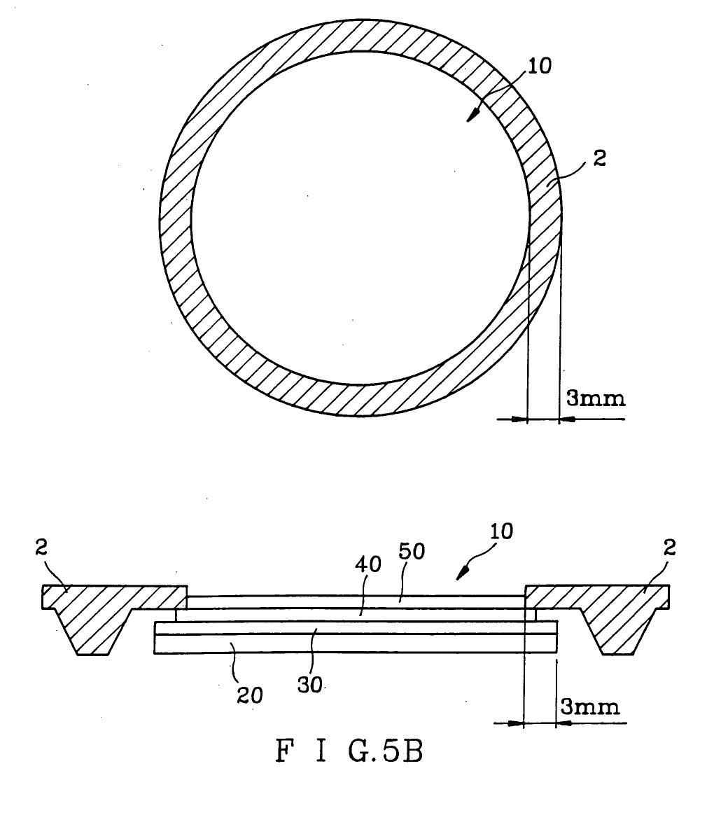

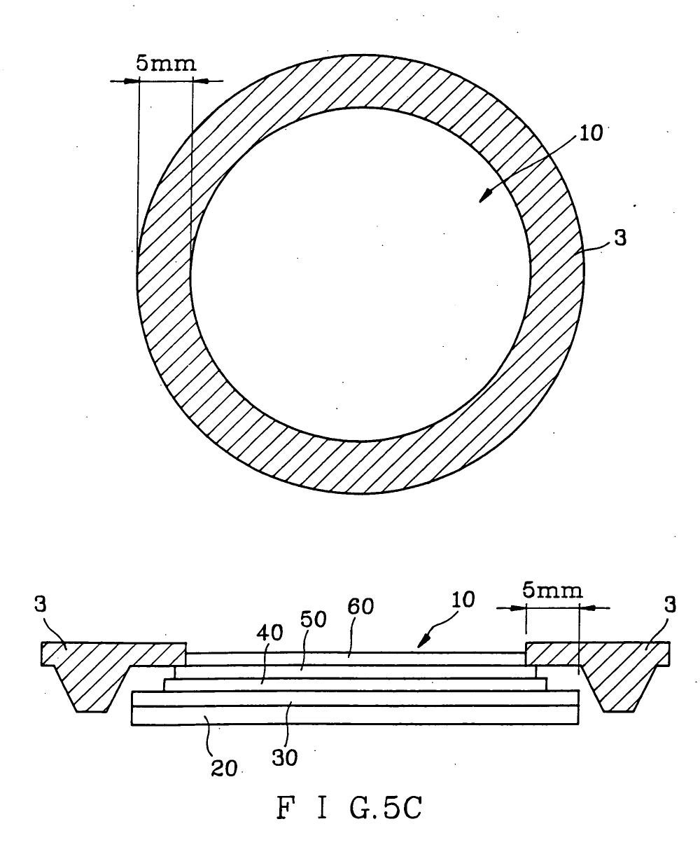

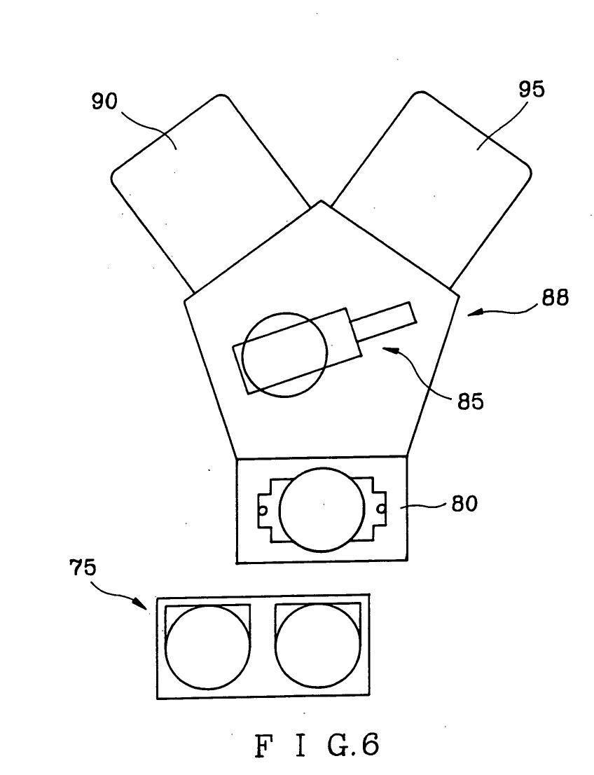

Referring now more particularly to FIG. 5A for further explaining the critical step (5) in this process. There is shown a wafer 10 in step (4) and it is held down by a quartz clamp ring 1 of 2 mm width. This wafer now has BPSG 30 as its top layer. A Ti/TiN bilayer 40 is then sputtered onto the wafer 10, with the result that near the edge of the wafer 10 is a 2 mm wide band of the BPSG layer not covered with Ti/TiN 40, but only the BPSG 30 film from the previous step. Thereafter referring now to FIG. 5B, tungsten metal is deposited by the following two steps: First, a tungsten nucleation layer 50 is formed on the wafer 10 using CVD in chamber A 90 (referring FIG. 6) by reducing the WF₆ by SiH₄:

WF₆(g)+SiH₄(g)→4W(s)+SiF4(g)+H₂(g).

The reaction pressure is about between 4.5 to 30 torr and reaction temperature is between 445 to 475° C. by Ar with 1000 to 3000 Sccm, N₂ with 300 to 500 Sccm, H₂ with 1000 to 1500 Sccm, SiH₄ with 5 to 10 Sccm and WF₆ with 10 to 20 Sccm.

This nucleation layer 50 is about between 500 to 800 angstroms thick. In this process, the silicon wafer 10 is held down by a quartz clamp ring 2 of 3 mm width, thus the ring 2 covers the 2 mm wide BPSG 30 layer and an additional 1 mm band of the Ti/TiN bilayer 40. No tungsten metal is deposited onto the BPSG 30 surface and no peeling will occur. Moreover, separating the formation of the nucleation layer 50 and the bulk deposition of tungsten into two CVD chambers enables better control of the nucleation layer thickness, and thus better protection for the Ti/TiN structure underneath.

After this step, referring now to FIG. 5C, the wafer 10 is transferred into CVD chamber B 95 (referring FIG. 6) from chamber A 90 (referring to FIG. 6) and held by a quartz clamp ring 3 which is about 5 mm wide, then tungsten metal 60 is bulk deposited onto the tungsten nucleation layer 50 on the wafer 10 with between 7500 to 8000° by reducing WF₆ with H₂ employing CVD and the following reaction:

WF₆(g)+H₂(g)→W(s)+HF(g)

The reaction pressure is about between 70 to 90 torr and reaction temperature is between 445 to 475° C. by Ar with 2000 to 4000 Sccm, N₂ with 300 to 500 Sccm, H₂ with 500 to 1500 Sccm and WF₆ with 10 to 20 Sccm.

The tungsten-plug in the contact hole is formed by plasma anisotropic etchback technique.

This is followed by sputtering an Ai/Si/Cu layer and pattern metal lines by etching out unwanted Ti, TiN and Al/Si/Cu employing conventional etching and lithography technology.

The tungsten nucleation layer 50 made in chamber A 90 (referring FIG. 6) can be used as a passivation layer to prevent the WF₆ penetrating the TiN layer and reacting with Ti to form TiF₄ during the bulk deposition of tungsten in chamber B 95 (referring to FIG. 6). By depositing tungsten using two different quartz claim rings and two chambers facilitates the elimination of the volcano phenomena as mentioned above. Therefore, the overall yield of the process is increased by producing fewer devices with defects and the particle contamination of wafer will be avoided also.

FIG. 6 shows the system for the performing the process of the invention. First, the operator loads cassettes filled with wafers into the cassette indexer 75 which has two stages. Then the robot 85, located inside the loadlock chamber 88, moves the wafers one at a time from the cassette to slots in the storage elevator 80, which is also located inside the loadlock chamber 88. After the loadlock chamber 88 is pumped down to a low pressure, the robot 85 moves a wafer into chamber a 90 for depositing the nucleation layer, and then robot 85 transfers the nucleated wafer to chamber B95 for bulk deposition. When processing of the wafer is completed, the wafer transfer sequence is reversed and the wafer is moved out of the chamber B 95 to the cassette by through the storage elevator 80. Finish the operator can remove the cassette with wafers from the system.

What is claimed is:

1. In a process for manufacturing by chemical vapor deposition a tungsten-plug in a semiconductor device which comprises depositing a SiO₂ insulation layer on top of a substrate by CVD, then depositing a layer of BPSG onto the SiO₂ layer for surface planarization by employing CVD again; partially etching the SiO₂ layer and the BPSG layer to form a contact hole to the substrate; performing ion implantation through the contact hole and forming the device in the substrate; sputter depositing a barrier metal layer comprising a Ti and TiN bilayer in which the Ti metal is underneath the TiN in the Ti/TiN bilayer; wherein the improvement comprises depositing tungsten metal in two CVD chambers with different quartz clamp rings to control the area and thickness of the nucleation layer (50) and bulk deposition area of the tungsten layer (60) in order to ensure that the bulk deposition of tungsten is onto the nucleation layer; forming the tungsten-plug in the contact hole by a plasma anisotropic etch back procedure; and sputtering an Al/Si/Cu layer and pattern metal lines by conventional techniques.

2. A process for manufacturing a tungsten-plug avoiding volcano phenomena according to claim 1, wherein a quartz clamp ring which is about 2 mm wide is employed to form the Ti and TiN.

3. A process for manufacturing a tungsten-plug avoiding volcano phenomena according to claim 1, wherein the quartz clamp ring employed to form tungsten nucleation layer by CVD is about 3 mm wide.

4. A process for manufacturing tungsten-plug avoiding volcano phenomena according to claim 1, wherein the quartz clamp ring employed to form the bulk deposition of tungsten onto the tungsten nucleation layer is 5 mm wide.

5. A process for manufacturing tungsten-plug avoiding volcano phenomena according to claim 1, wherein the tungsten nucleation layer deposited by CVD is about 500 angstroms thick.

6. In a process for manufacturing by chemical vapor deposition a tungsten-plug in a semiconductor device which comprises depositing a SiO₂ insulation layer on top of a substrate by CVD, then depositing a layer of BPSG onto the SiO₂ layer for surface planarization by employing CVD again; partially etching the SiO₂ layer and the BPSG layer to form contact holes to the substrate; making ion implantation through the contact holes and forming the device in the substrate; sputter depositing a barrier metal layer comprising Ti and TiN bilayer, in which the Ti metal is underneath the TiN in the Ti/TiN bilayer; wherein the improvement comprises holding the BPSG coated wafer in place with a first quartz ring having a diameter to form a first band and sputter depositing a barrier metal layer made up of Ti and TiN, onto the exposed BPSG layer in which the Ti metal is underneath the TiN layer, said barrier layer is not formed in the band width of said first ring band;
forming a tungsten nucleation layer on the wafer in one chemical vapor deposition chamber using a second clamp quartz ring with a second diameter and a second band width which covers the first band and a small portion of the TiN/Ti barrier layer, by reacting WF₆ with SiH₄ to form a nucleation layer except in the band covered by said first and second quartz rings; transferring the thus treated wafer to a second vapor deposition chamber in which a third clamp ring is employed, said third clamp having a third diameter and third band width which covers the first and second band widths and a small portion of the wafer having the tungsten nucleation layer; forming a bulk tungsten layer in the second chamber by the reaction of WF₆ with H₂ to produce the bulk deposition of W onto tungsten nucleation layer of the wafer to cover contact holes;
forming the tungsten-plug in the contact hole by plasma anisotropic etchback technique.

7. The process of claim 6, wherein the quartz clamp ring employed during the formation of Ti and TiN by CVD is about 2 mm wide.

8. The process of claim 6, wherein the quartz clamp ring employed to form tungsten nucleation layer by CVD is about 3 mm wide.

9. The process of claim 6, wherein the quartz clamp ring employed to form the bulk deposition of tungsten onto the tungsten nucleation layer is 5 mm wide.

10. The process of claim 6, wherein the tungsten nucleation layer deposited is about 500 angstroms thick.

11. A process for making a tungsten-plug in an integrated circuit device which comprises the steps of:
(1) Depositing a SiO₂ insulation layer (25) on top of a substrate (20) by CVD; and then depositing a layer of BPSG (30) onto the SiO₂ layer (20) for surface planarization by again employing CVD;
(2) Partially etching the SiO₂ insulation layer (25) and the BPSG layer (30) to form contact holes on the substrate (20);
(3) Making ion implantation through the contact hole and forming the devices;
(4) Sputter depositing a barrier metal layer made up of Ti followed by rapid thermal nitridation to form a TiN layer in which the Ti metal is underneath the TiN layer which is bilayer (40);
(5) Depositing tungsten (W) metal in two CVD chambers with different quartz clamp rings to control the area and thickness of the tungsten nucleation layer (50) and bulk deposition area of the tungsten (W) layer (60) in order to ensure the bulk deposition is onto the nucleation layer;
(6) Forming the tungsten-plug in the contact hole by plasma anisotropic etch back technique;
(7) Sputtering on a Al/Si/Cu layer and pattern metal lines by conventional technology.

12. The process of claim 11, wherein the rapid thermal nitridation of step (4) takes place at about 760° C. for about 30 seconds.
